(19) United States
(12) Patent Application Publication
(10) Pub. No.: US 2003/0172333 A1
(43) Pub. Date: Sep. 11, 2003

(54) Built-in self test parallel JTAG serial chain architecture for reduced test vector size

(76) Inventor: Eric R. Wehage, Tenino, WA (US)

Correspondence Address: Michael J. Mallie, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/095,359

(22) Filed: Mar. 8, 2002

(51) Int. Cl. G01R 31/28

(52) U.S. Cl. 714/726; 714/733

(57) ABSTRACT

A system and method for programming built-in self-testing (BIST) state machines to test integrated circuit components are disclosed. The standard Joint Test Action Group method for programming BIST state machines is modified to increase speed and efficiency. The registers containing the instructions for BIST testing are connected in parallel, as opposed to the standard serial connections, allowing the registers to be fed instructions simultaneously. This cuts down the required time to feed test instructions to the BIST state machines. The addition of multiple shadow registers to each register further cuts down the required time to feed test instructions to the BIST state machines.

### FIELD OF THE INVENTION

The field of the invention relates to integrated circuit (IC) component testing. More specifically, it relates to the transmission of data to and from built in self test (BIST) state machines for random access memories.

### BACKGROUND OF THE INVENTION

One method for testing components on an integrated circuit (IC) 100, specifically random access memories (RAM) 110, is direct access testing (DAT), as shown in FIG. 1. In direct access testing, external testing devices are connected to output pins 120 leading directly to the component. DAT is problematic when testing involves an IC 100 that has a large number of RAMs 110. RAMs 110 have numerous signals, requiring the routing of several leads 130 to the edge of the RAM integrated circuit. Further, the leads must be routed to only a few input/output (I/O) devices. The greater the number of RAMs 110 compared to the number of IO pins 120, the larger multiplexers (muxes) 140 need to be, increasing the required routing. Routing channels become limited, which causes the routing channels to be too long and not meet timing specifications. A large amount of support logic is required.

DAT works well for components that have may have one or two RAMs in the chip, but not for chips that have more than two RAMs.

An alternative testing method includes placing built-in self-test (BIST) state machines 200 in IC 100, as shown in FIG. 2. BIST 200 is an engine built in the IC 100 that is connected directly to RAM 110. Joint Test Action Group (JTAG) is the most common method used to access the BIST logic, but other methods are available. The JTAG specification is maintained by the Institute of Electrical and Electronics Engineers (IEEE) as the IEEE Std 1149.1-1990, and IEEE Std 1149.1a-1993 “IEEE Standard Test Access Port and Boundary-Scan Architecture.” In some implementations of BIST (200), BIST 200 does not actually perform a self-test on its own. In some cases, BIST 200 requires some external information (e.g., instructions) to perform the self-test. Data, including instructions, micro operations, or things of that nature, allows BIST 200 to perform the self-test procedures.

Implementing a BIST 200 that is not completely self-sustaining saves space on the die because the chip contains micro-operation supports instead of embodying a macro operation that performs the entire operation. The micro-operation supports require a test vector to be imported to perform the macro operation. An off-chip device concatenates all the different micro operations, stores them up into a test vector, and executes one micro operation at a time until the entire test suite is completed.

The BIST device is accessed through a JTAG or test access port (TAP) port. JTAG ports include a five pin port as part of a serial shift chain, as shown in FIG. 3. One pin 300 is a test data input (TDI) and a second pin 310 is a test data output (TDO). A JTAG TAP controller 315 manages the transfer of data between the TDI pin and the TDO pin. The JTAG port also specifies three additional signals to the TAP controller: a test mode select signal (TMS) 320, a TAP controller reset signal (TRST) (330), and a shift routine clock signal (TCK) 340. The JTAG specification requires the TAP controller include a TAP state machine (TAP SM) that goes through sets of states that are dependant upon the value of TCK 340. The state of the TAP SM determines the actions of the shift chain. The shift chain is a serial shifting chain between TDI 300 and TDO 310 connected by registers 350. Registers 350 are connected in a serial fashion and each one of registers 350 receives a control signal. Registers 350 are made up of one-bit flip-flops. One of these control signals is a shift control signal 360 generated from the state machine on JTAG TAP controller 315. When shift control signal 360 is asserted and the flops receive a TCK signal 340, the bits are shifted through the registers 350. The JTAG specification further specifies a set of shadow registers 370 designed to hold values during shift operations.

In addition to shift control signal 360, JTAG requires two more shift signals, called update signal 380 and capture signal 390. If update signal 380 is asserted, when a TCK 340 edge occurs, the values that are held in the shift chain are loaded into shadow registers 370. If the capture signal 390 is asserted, then the values of shadow registers 370 are captured into shift registers 350. JTAG logic implements update signal 380 and capture signal 390 when a set of bits comprising a set of instructions is at the proper position in the chain. After capture signal 390, the test results are shifted out TDO pin 310.

As shown in FIG. 4, the JTAG method of transferring test data can be applied to loading instructions and receiving test data from BIST state machines. Instructions are input on TDI pin 300. The instructions are then shifted along serially connected registers 400 and transferred to BIST state machines 410, which execute the instructions to test RAMs 420 or other components. The results of these tests are then transferred from BIST state machines 410 back to registers 400 and the results are then shifted out TDO pin 310.

Like DAT testing, standard JTAG BIST testing works relatively efficiently when the IC contains a small number of RAMs or other components to be tested. When more than a small RAMs are present, the efficiency of this method decreases greatly. Regardless of how many BIST state machines are being activated to test a component, the same number of bits must be passed to ensure that the data instructions reach the proper destination. The size of the JTAG chain increases with the number of BIST units connected, thereby increasing the size of the test vector. For example, for instructions equaling 24 bits in length, with 50 RAMs on a chip, 1200 bits must be passed. Depending on the speed that the bits are transmitted, the testing of a single chip can take several minutes.

### BRIEF DESCRIPTION OF THE DRAWINGS

The present invention is illustrated by way of example and not limitation in the figures of the accompanying drawings in which like references indicated similar elements and in which:

FIG. 1 is a block diagram of a prior art integrated circuit (IC) that uses direct access testing (DAT) to test components on an IC.

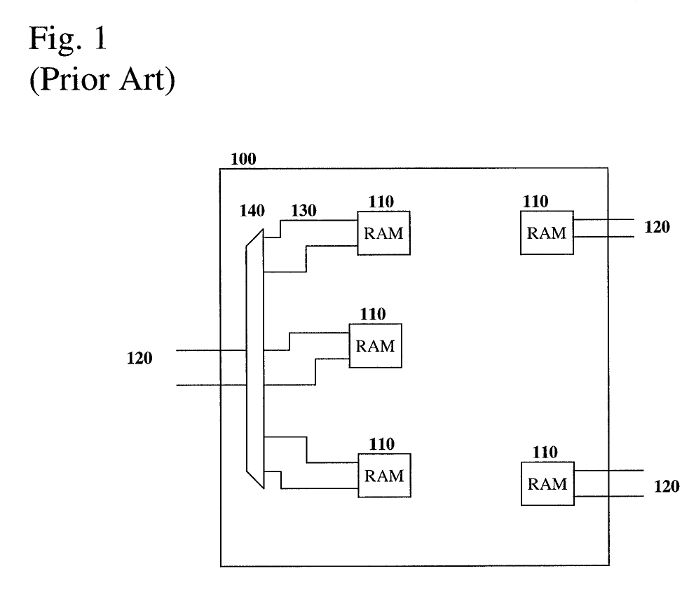

FIG. 2 is a block diagram of a prior art IC that uses built-in self-test (BIST) state machines to test components on an IC.

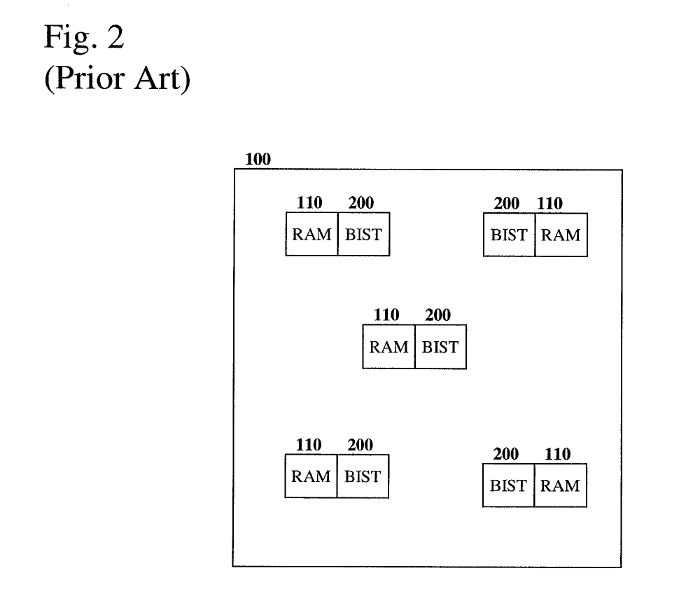

FIG. 3 is a block diagram of a prior art shift chain specified by the joint test action group (JTAG).

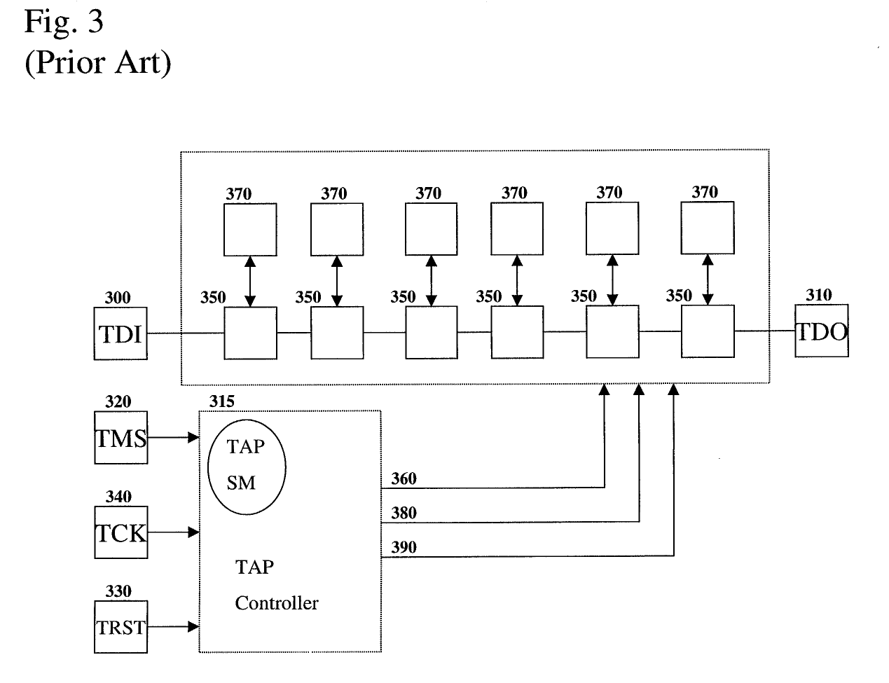

FIG. 4 is a block diagram of a prior art IC that uses JTAG programmed BIST state machines to test components on an IC.

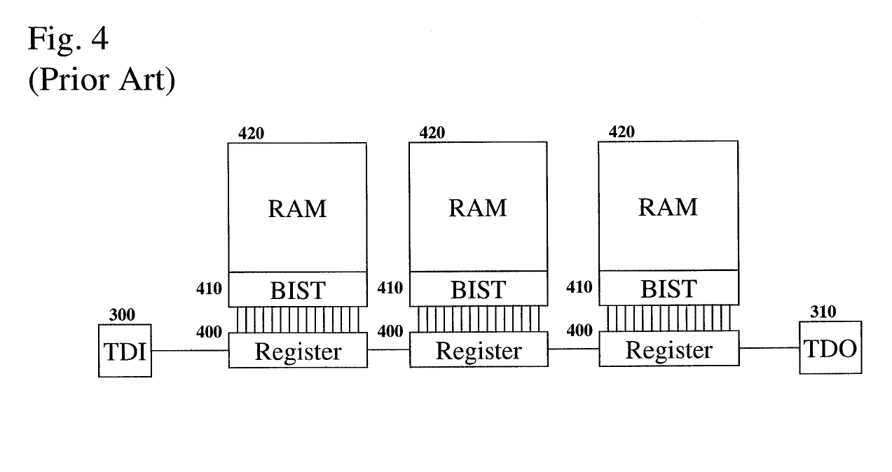

FIG. 5 is a block diagram of one embodiment of a parallel JTAG chain structure.

FIG. 6 is a block diagram of one embodiment of JTAG shadow register indexing.

FIG. 7 is a block diagram of one embodiment of a BIST ID shadow register.

FIG. 8 is a block diagram of one embodiment of a family ID shadow register

FIG. 9 is a diagram of one embodiment of a family ID.

### DETAILED DESCRIPTION

A system and method are described for programming built-in self-testing (BIST) state machines to test integrated circuit (IC) components. The techniques described herein is a modified approach to the standard Joint Test Action Group method for programming BIST state machines, resulting in an increase in speed and efficiency. The registers storing the instructions for BIST testing are connected in parallel, as opposed to the standard serial connections, allowing the registers to be fed instructions simultaneously. The addition of multiple shadow registers to each register further reduces the required time to feed test instructions to the BIST state machines.

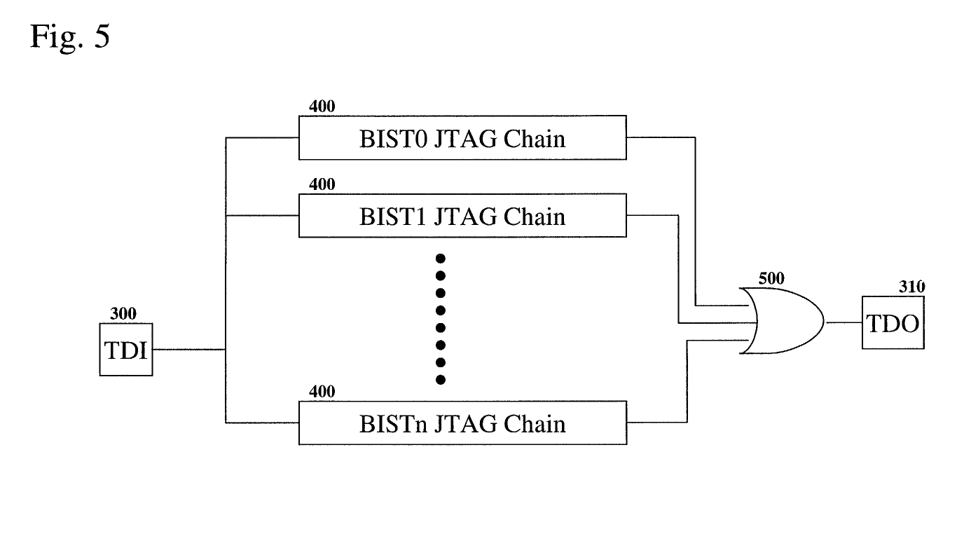

In one embodiment, each BIST state machine 410 has a shift chain 400 connected in parallel with shift chains 400 of other BIST state machines, as shown in FIG. 5. This arrangement can include as many shift chains as necessary to accommodate each BIST state machine 410. In alternate embodiment, a set of serially connected shift chains can be interspersed with a set of parallel shift chains. By connecting the BIST shift chains 400 in parallel, redundancy among the test vectors is reduced. In one embodiment, each chain is identical in length and definition, so each BIST receives the same command and can execute the same set of tests. As the results of the test are shifted out, results are combined into a single result using a logical OR gate 500, which may comprise a series of OR gates, before being output at the TDO JTAG pin 310.

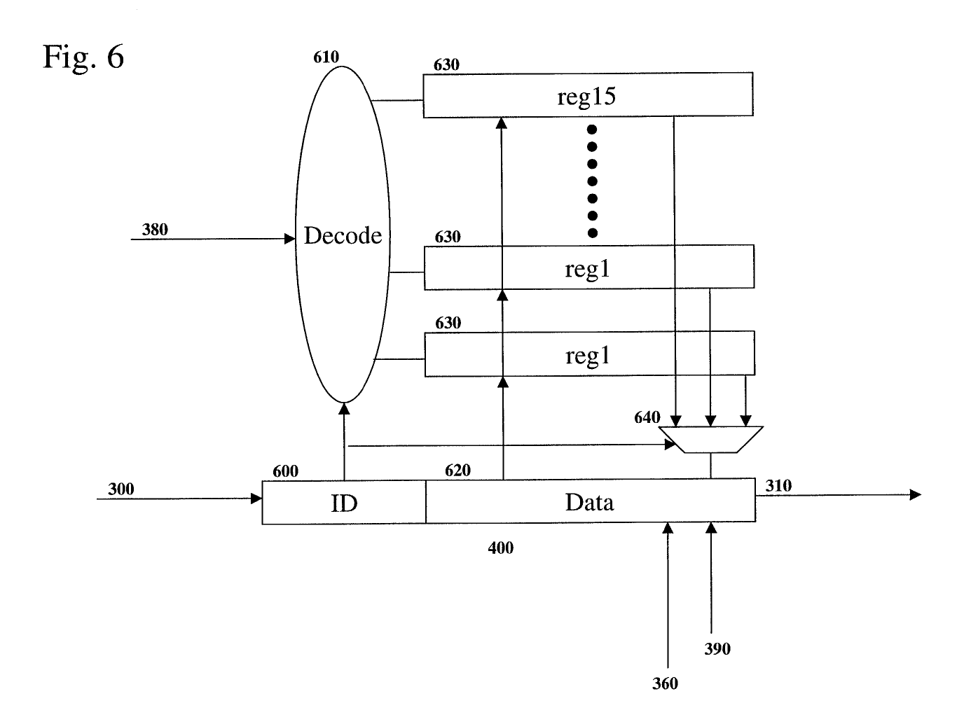

In one embodiment, redundant JTAG shifting is further reduced by increasing the number of shadow registers associated with each register, as shown in FIG. 6. The shadow registers hold values during shift operations. In one embodiment, the JTAG shift chain 500 is divided into at least two parts. The first part is an identification field (600), which is used by the register decode logic 610 to identify to which of the shadow registers the data is being sent when update signal 380 is asserted. The second part is a data field 620, which is the information that is being sent to an indicated shadow register 630.

In one embodiment, the shift chain is 20 bits long, with 4 bits representing the ID and 16 bits representing the data. With 4 bits as ID 600, up to 16 shadow registers 630 can be utilized. To increase the number of shadow registers 630 beyond 16, the number of bits used as ID 600 is increased. In one embodiment, ID bits 600 do not have a shadow flip-flop associated with them. The data can take the form of instructions for micro operations to be performed by the BIST state machine 410.

Once BIST state machine 410 has performed the tests, the results are then loaded into shadow registers 630. Using the ID as a key 600, the test results in shadow registers 630 are muxed 650 back into register 610 upon assertion of capture signal 390. The results are then shifted out the TDO pin 310 upon assertion of shift signal 360.

Further embodiments allow the output TDO to differentiate between different BIST units. Such differentiation assists in failure analysis and in giving BIST units different command sets during the test phase. In one embodiment, individual BIST units are selected. In a second embodiment, BIST units with similar properties or functions are selected at the same time. In these embodiments, BIST units that are not selected are not allowed to respond to commands. Further, the shift chains of these units are set to 0 to ensure that they do not affect the values captured by another BIST unit while shifting through OR gates 500 to TDO pin 310. Both embodiments use a dedicated ID shadow register in the shadow registers available. The least significant bit of the dedicated shadow register or shadow registers is defined as the “BIST select flag”. In one embodiment, the least significant bit being “1” indicates the BIST unit is selected and will respond to commands and a least significant bit being “0” indicates the BIST unit is not selected and will not respond to command updates other that to the BIST select flag. In one embodiment that incorporates elements of both embodiments, two shadow registers are dedicated ID shadow registers and the BIST unit is limited to command updates from both shadow registers while not selected.

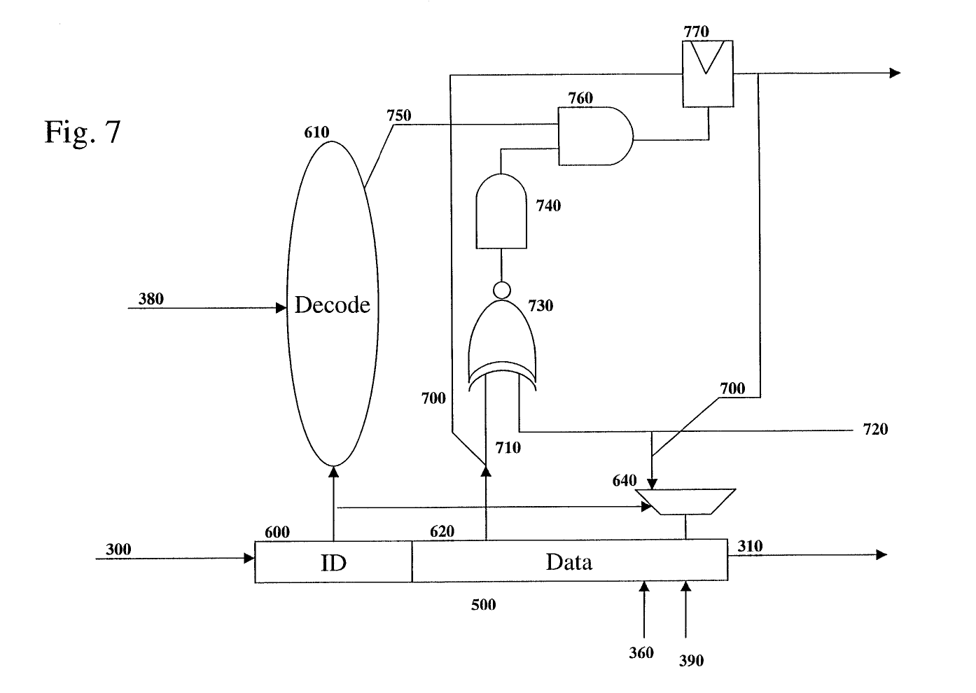

One embodiment of a mechanism for selecting individual BIST units is shown in FIG. 7. The individual BIST ID is stored in a dedicated shadow register. The least significant bit 700, or bit “0”, contains an indication to read or write the BIST select flag. The remaining upper bits 710 of the shadow register represent a unique BIST ID value. An attempt to update this shadow register causes a comparison to be made between the value of the BIST unit's individual ID 720 and the value of attempted update 710. In one embodiment, the comparison is performed by XNOR gate 730. AND gate 740 combines the result of XNOR gate 730 comparison. Decode logic 610 sends a signal 750 that the BIST ID dedicated shadow register is being accessed. AND gate 760 determines that the comparison was successful and the BIST ID dedicated shadow register access signal 750 is asserted, causing BIST select flag 770 to be enabled. BIST select flag 770 is changed to reflect least significant bit 700. The BIST unit is selected or deselected and the BIST select flag status 770 and BIST unit ID 720 are muxed 640 back into data register 620, to be subsequently forwarded to the TDO output.

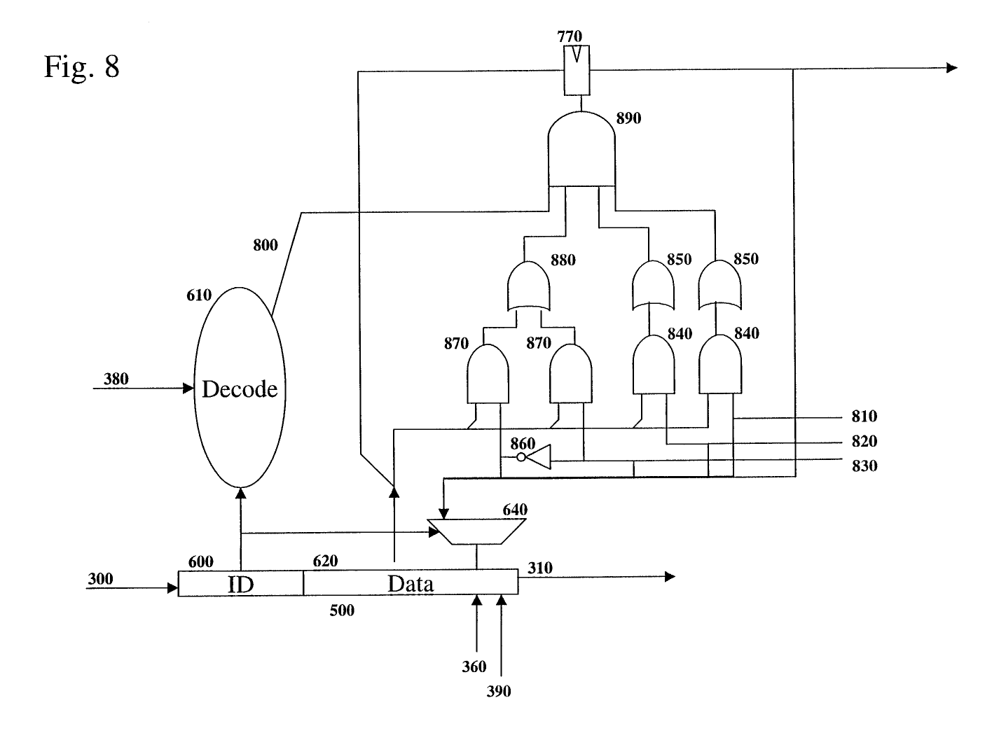

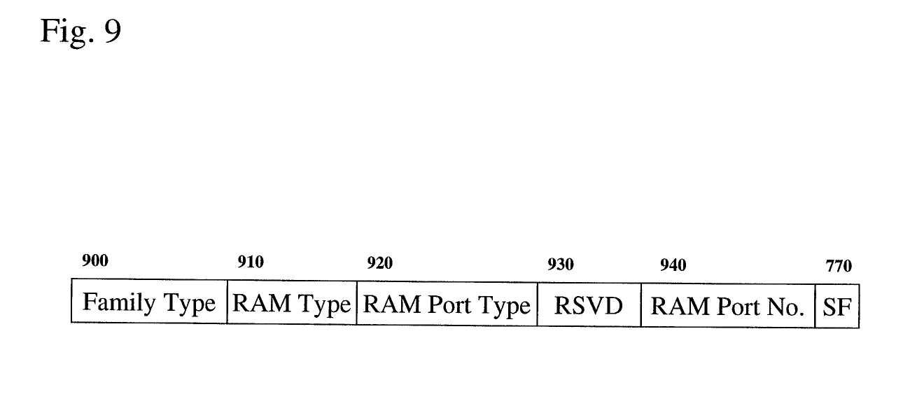

One embodiment of a mechanism for selecting BIST units with similar properties or functions all at once is shown in FIG. 8. By grouping BIST units with similar properties or functions, a single set of instructions can be sent to multiple BIST units, further reducing the time required for instruction input. A shadow register, different from the BIST unit ID shadow register, stores a family ID for the BIST unit. In one embodiment, the family ID is defined as illustrated in FIG. 9. In one embodiment, the family ID is 16 bits, although the size of the ID can be varied in different embodiments as necessary. First field 900 is the family type, which determines what the other fields represent. Family type field 900 is changed, subsequent fields are defined differently. The following fields represent an embodiment where family type field 900 is ‘00’. Second field 910 is the RAM type, which determines whether the RAM writes to memory when the clock goes from 0 to 1, called rising edge, or writes when the clock goes from 1 to 0, called late write. Third field 920 is the RAM port type, which in this example includes quad port, triple port, dual port and single port. Fourth field 930 is reserved for later definition. Fifth field 940 is RAM port number, which in this example includes the CAM port, and ports 0-3. The least significant bit is left as BIST select flag 770, regardless of family type field 900. In one embodiment, multiple categories may be selected in each field, but all fields have at least one matching category for the BIST unit to be selected.

In one embodiment, the mechanism of FIG. 8 compares the data commands with the family ID defined in FIG. 9 to determine if the BIST is selected. The mechanism of FIG. 8 operates similarly to the mechanism of FIG. 7. Decode logic 610 uses shadow register ID 600 to determine if the family ID is being asserted 800. The data in the transmission 620 is then compared with the port number 810, the RAM port type 820, and the RAM type 830 of the BIST unit to determine if the BIST unit is of the family of BIST units to receive instructions. In one embodiment, AND gates 840 compare the BIST port number and the BIST RAM port type with the appropriate field in the data transmission 620 to determine if one of the selected categories is matched for each field. If one of the selected categories is matched, the OR gate 850 for that field is asserted. For the RAM type field 830, the rising edge status and an inverted 860 late write status are each compared by AND gates 870. The output of each AND gate is then entered into an OR gate 880, allowing a single match to produce a positive effect. This arrangement allows the instructions to indicate late write status, rising edge status, or both. A logical AND gate 890, determining that each field has a match and that the proper shadow register has been asserted 800, enables the BIST select flag 770 to be selected or deselected using the least significant bit in the register.

Although the present invention has been described with reference to specific exemplary embodiments, it will be evident that various modifications and changes may be made to these embodiments without departing from the broader spirit and scope of the invention. Accordingly, the specification and drawings are to be regarded in an illustrative rather than a restrictive sense.

What is claimed is:

1. An integrated circuit, comprising:
a plurality of built in self testing (BIST) state machines to test a set of integrated circuit components; and
a plurality of shift chains of registers, each of the plurality of shift chains of registers being coupled to one of the plurality of BIST state machines to store a set of data related to the one BIST state machine, with at least two of the shift chain of registers being connected in parallel.

2. The integrated circuit of claim 1, wherein each of the shift chains of registers includes an input pin to allow an exterior set of data to be fed to the shift chain of registers.

3. The integrated circuit of claim 1, wherein each of the shift chains of registers includes an output pin to allow a set of data to be retrieved.

4. The integrated circuit of claim 3, further comprising at least one logical OR gate to connect the parallel connected shift chains of registers to the output pin.

5. The integrated circuit of claim 1, wherein the set of data related to the BIST state machine is a set of instructions for execution by the BIST state machine.

6. The integrated circuit of claim 1, wherein the set of data related to the BIST state machine is a set of test results produced by the BIST state machine.

7. The integrated circuit of claim 1, further comprising sets of shadow registers coupled to the plurality of shift chains of registers, the shadow registers for transferring data between the BIST state machine and the shift chain of registers.

8. The integrated circuit of claim 7, further comprising an update signal coupled to a test access port controller to enact a transfer of the set of data stored in the shift chain of registers to the at least one set of shadow registers.

9. The integrated circuit of claim 7, further comprising:
a test access port controller; and
a capture signal coupled to the test access port controller to enact a transfer of the set of data stored in the at least one set of shadow registers to the shift chain of registers.

10. The integrated circuit of claim 7, further comprising a plurality of sets of shadow registers connected in parallel to each shift chain of registers.

11. The integrated circuit of claim 1, wherein the set of data related to the BIST state machine includes an identification number.

12. The integrated circuit of claim 11, wherein the identification number indicates a BIST state machine that the set of data is targeted to.

13. The integrated circuit of claim 11, wherein the identification number indicates the BIST state machine that the set of data is targeted to.

14. The integrated circuit of claim 11, wherein the identification number indicates a family of BIST state machines that the set of data is targeted to.

15. An integrated circuit, comprising:
a plurality of built in self testing (BIST) state machines to test the set of integrated circuit components;
a plurality of shift chains of registers, wherein each of the plurality of shift chains of registers is coupled to one of the plurality of BIST state machines to store a set of data related to the one BIST state machine; and
a plurality of sets of shadow registers for each register to transfer data between the BIST state machine and the shift chain of registers.

16. The integrated circuit of claim 15, wherein the set of data related to the BIST state machine is a set of instructions for execution by the BIST state machine.

17. The integrated circuit of claim 15, wherein the set of data related to the BIST state machine is a set of test results produced by the BIST state machine.

18. The integrated circuit of claim 15, further comprising:
a test access port controller; and
an update signal coupled to the test access port controller to enact a transfer of the set of data stored in the shift chain of registers to at least one of the plurality of sets of shadow registers.

19. The integrated circuit of claim 18, wherein the set of data related to the BIST state machine includes an identification number indicating which set of shadow registers to transfer the set of data to.

20. The integrated circuit of claim 15, further comprising a capture signal to coupled to a test access port controller to enact a transfer of the set of data stored in one of the plurality of sets of shadow registers to the shift chain of registers.

21. The integrated circuit of claim 20, wherein the set of data related to the BIST state machine includes an identification number indicating which set of shadow registers the set of data was received from.

22. The integrated circuit of claim 15, wherein the set of data related to the BIST state machine includes an identification number.

23. The integrated circuit of claim 22, wherein the identification number indicates a BIST state machine that the set of data is targeted to.

24. The integrated circuit of claim 22, wherein the identification number indicates a family of BIST state machines that the set of data is targeted to.

25. A method, comprising:
executing instructions with a plurality of built in self testing (BIST) state machines and a plurality of shift chains of register on an integrated circuit to test at least one component of the integrated circuit, wherein at least one of the plurality of shift chains of registers is connected to each BIST state machine to store a set of data related to the BIST state machine and is connected to another of the plurality of shift chains of registers in parallel; and
shifting data from one or the parallel-connected shift chains of registers into one of two sets of shadow registers associated with the one parallel-connected shift chain of registers.
